(19) United States
(12) Patent Application Publication
(10) Pub. No.: US 2008/0280391 A1
(43) Pub. Date: Nov. 13, 2008

(54) METHODS OF MANUFACTURING MOS TRANSISTORS WITH STRAINED CHANNEL REGIONS

(75) Inventors: Dong-Suk Shin, Gyeonggi-do (KR); Joo-Won Lee, Gyeonggi-do (KR); Tae-Gyun Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/112,562

(22) Filed: Apr. 30, 2008

(30) Foreign Application Priority Data
May 10, 2007 (KR) 10-2007-0045314
Jun. 19, 2007 (KR) 10-2007-0059704

(51) Int. Cl. H01L 21/02

(52) U.S. Cl. 438/104; 257/E21.002

(57) ABSTRACT

In some methods of manufacturing transistors, a gate electrode and a gate insulation layer pattern are stacked on a substrate. Impurity regions are formed at portions of the substrate that are adjacent to the gate electrode by implanting Group III impurities into the portions of the substrate. A diffusion preventing layer is formed on the substrate and covering the gate electrode. A nitride layer is formed on the diffusion preventing layer. The substrate is thermally treated to form a strained silicon region in the substrate between the impurity regions and to activate the impurities in the impurity regions. A high performance PMOS transistor and/or CMOS transistor may thereby be manufactured on the substrate.

### CROSS-REFERENCE TO RELATED APPLICATIONS

This application claims priority under 35 U.S.C. § 119 to Korean Patent Application No. 10-2007-0045314 filed on May 10, 2007 and Korean Patent Application No. 10-2007-0059704 filed on Jun. 19, 2007, the entire contents of which are herein incorporated by reference in their entireties.

### BACKGROUND OF THE INVENTION

1. Field of the Invention

The present invention relates to methods of manufacturing transistors and, more particularly, to methods of manufacturing metal oxide semiconductor (MOS) transistors.

2. Description of the Related Art

Semiconductor devices have rapidly developed as information-processing circuits, such as a processors, and are being incorporated into more diverse types of electrical and electronic apparatuses. Semiconductor devices are increasingly being required to provide higher response speeds and greater storage capacity. To satisfy these requirements, manufacturing technologies are continuing to be sought that improve integration density, reliability, and/or response speeds of semiconductor devices.

Metal oxide semiconductor field effect transistors (MOSFET) can have high response speeds at low operating voltages, and can have small feature sizes that enable high integration densities.

A high response speed may be provided by forming a channel of a transistor in a strained silicon layer, which may improve the mobility of charge carriers such as electrons or holes in the transistor. The strained silicon layer can include a silicon layer in which a bonding length between silicon atoms is extended or shortened in accordance with a stress generated in the silicon layer.

A stress for improving the mobility of the electrons in the channel region of the strained silicon layer may be different from that for improving the mobility of the holes in the channel region. When an N type metal oxide semiconductor (NMOS) transistor and a P type metal oxide semiconductor (PMOS) transistor are formed on one substrate, stresses in channel regions of strained silicon layers of the NMOS and PMOS transistors are different from each other to increase currents between source and drain regions of the NMOS and the PMOS transistors.

When an NMOS transistor is formed on a single crystalline silicon substrate having a crystalline structure of (1 0 0), a channel region formed in the single crystalline silicon substrate may include a strained silicon layer in which a tensile stress is generated along a direction that is parallel to a length of the channel region. When mobility of electrons that are majority carriers in the NMOS transistor increases due to the strained silicon layer having the tensile stress, a current flowing between a source region and a drain region of the NMOS transistor may also increase so that the NMOS transistor may have an improved performance.

In contrast, when a PMOS transistor is formed on a single crystalline silicon substrate having a crystalline structure of (1 0 0), a channel region formed in the single crystalline silicon substrate may include a strained silicon layer in which a compressive stress is generated along a direction in parallel to a length of the channel region. When mobility of holes that are majority carriers in the PMOS transistor increases because of the strained silicon layer having the compressive stress, a current flowing between a source region and a drain region may increase such that the PMOS transistor may have an enhanced performance.

Since the stresses in the channel regions of the NMOS and the PMOS transistors having high performances are different from each other, it can be difficult to form such NMOS and the PMOS transistors on a common substrate. For example, U.S. Patent Application Publication No. 2005/136583 discloses a method of manufacturing an improved transistor by adjusting a stress in a channel region. In the above U.S. Patent Application Publication, a gate electrode and source/drain regions are formed on a silicon substrate, and then a capping layer having a tensile stress is formed on the gate electrode and the source/drain regions. Thereafter, an annealing process is performed on the substrate to form strained silicon having a high tensile stress in a channel region beneath the gate electrode. When the channel region includes the strained silicon having the high tensile stress, however, a PMOS transistor may not be properly formed on the substrate because a mobility of holes in the channel region may be reduced as mentioned above. Further, additional processes may be required to prevent a tensile stress from being generated in an area of the substrate whereas a PMOS transistor is formed when the PMOS transistor is formed together with an NMOS transistor on a common substrate.

### SUMMARY OF THE INVENTION

Some embodiments of the present invention provide methods of manufacturing a P type MOS (PMOS) transistor which can have improved electrical characteristics.

Some other embodiments of the present invention provide methods of manufacturing a complementary MOS (CMOS) transistor which can have improved electrical characteristics.

According to one aspect of the present invention, a method of manufacturing a transistor includes forming a gate electrode stacked on a gate insulation layer pattern on a substrate. Impurity regions are formed at portions of the substrate adjacent to the gate electrode by implanting Group III impurities into the portions of the substrate. A diffusion preventing layer is formed on the substrate and covers the gate electrode. A nitride layer is formed on the diffusion preventing layer. The substrate is thermally treated to form a strained silicon region in the substrate between the impurity regions while activating the impurities in the impurity regions. The thermal treatment of the substrate can form the strained silicon region in the substrate to extend between the impurity regions.

Formation of the diffusion preventing layer may include forming an oxide layer on the substrate and covering the gate electrode, and then treating the oxide layer with a plasma. The plasma may be generated from at least one of a hydrogen gas, a helium gas, a nitrogen gas, an argon gas, an oxygen gas, and an ozone gas. The oxide layer may include a tensile strained silicon oxide layer or a compressive strained silicon oxide layer. The oxide layer may be treated at one or more temperatures in a range between about 300° C. and about 700° C.

Formation of the diffusion preventing layer may include forming an oxide layer on the substrate and covering the gate electrode, and then treating the oxide layer with ultraviolet light.

In some further embodiments, impurities may be implanted into the portions of the substrate and a portion of the gate electrode before forming the impurity regions so that the implanted portions of the substrate and the gate electrode have non-crystalline structures. The impurities may be selected from at least one of germanium, xenon, carbon, and fluorine.

According to another aspect of the present invention, the manufacturing of a transistor can include formation of gate structures in a first area and a second area of a substrate. Each of the gate structures includes a gate electrode stacked on a gate insulation layer pattern. First impurity regions are formed at first portions of the substrate adjacent to the gate structure in the first area by implanting therein first impurities having a first conductivity. Second impurity regions are formed at second portions of the substrate adjacent to the gate structure in the second area by implanting therein second impurities having a second conductivity. A diffusion preventing layer is formed on the substrate and covering the gate structures, and a nitride layer is formed on the diffusion preventing layer. The substrate is thermally treated to form a first strained silicon region in the substrate between the first impurity regions, to form a second strained silicon region in the substrate between the second impurity regions, and to activate the first and the second impurities in the first and the second impurity regions.

In some further embodiments, the oxide layer may be formed by a thermal chemical vapor deposition process using tetraethylorthosilicate, a plasma enhanced chemical vapor deposition process, and/or a high density plasma-chemical vapor deposition process.

In some further embodiments, the treatment of the oxide layer and formation of the nitride layer may be performed in-situ in a chamber without breaking a vacuum seal. Alternatively, the treatment of the oxide layer may be carried out after forming the nitride layer.

Formation of the diffusion preventing layer may include forming an oxide layer on the substrate and covering the gate structures, and then treating the oxide layer with ultraviolet light.

In some embodiments, the diffusion preventing layer may have a thickness in a range between about 50 Å and about 300 Å.

In some further embodiments, the substrate may be thermally treated at one or more temperatures in a range between about 900° C. and about 1,200° C. and in an atmosphere including nitrogen, argon, and/or hydrogen.

In some further embodiments, the nitride layer may be formed at one or more temperatures in a range between about 300° C. and about 500° C. through at least one of a plasma enhanced chemical vapor deposition process and a high density plasma-chemical vapor deposition process. The nitride layer may have a thickness in a range between about 100 Å and about 1,000 Å.

In some further embodiments, gate spacers may be formed on sidewalls of each of the gate structures. The nitride layer and the diffusion preventing layer may be removed after thermally treating the substrate. Metal silicide patterns may be formed on the substrate and the gate structure.

In some further embodiments, impurities may be implanted into the first and the second portions of the substrate and portions of the gate electrodes before forming the first and the second impurity regions so that the first and the second portions of the substrate and portions of the gate electrodes have non-crystalline structures. The impurities may be selected from the least one of germanium, xenon, carbon, and fluorine

In some further embodiments, the first impurities may include phosphorus or arsenic, and the second impurities may include boron or boron fluoride. A nitride layer pattern may be formed in the first area by partially removing the nitride layer in the second area.

According to still another aspect of the present invention, a method of manufacturing a metal oxide semiconductor transistor and include forming gate structures in a first area and a second area of a substrate. Each of the gate structures includes a gate electrode stacked on a gate insulation layer pattern. First impurity regions are formed at first portions of the substrate adjacent to the gate structure in the first area by implanting first impurities having a first conductivity. Second impurity regions are formed at second portions of the substrate adjacent to the gate structure in the second area by implanting second impurities having a second conductivity. An oxide layer is formed on the substrate and covering the gate electrodes. The oxide layer is treated to form a diffusion preventing layer having an increased energy level to further inhibit diffusion of the first and the second impurities. A nitride layer is formed on the diffusion preventing layer. The substrate is thermally treated to form a first strained silicon region in the substrate between the first impurity regions, to form a second strained silicon region in the substrate between the second impurity region, and to activate the first and the second impurities in the first and the second impurity regions.

In some further embodiments, the oxide layer may be treated by irradiating the oxide layer with ultraviolet light. A nitride layer pattern may be formed in the first area by partially removing the nitride layer in the second area.

Some embodiments of the present invention may thereby manufacture a PMOS transistor having improved electrical characteristics by the formation of a strained region in a substrate portion thereof. Further, an N type MOS (NMOS) transistor and the PMOS transistor may have high on-currents without necessitating use of additional processes to improve the electrical characteristics of the PMOS transistor. Accordingly, a CMOS transistor having improved electrical characteristics may thereby be more easily manufactured on the substrate.

### BRIEF DESCRIPTION OF THE DRAWINGS

The above and other features and advantages of the present invention will become more apparent by describing in detailed example embodiments thereof with reference to the accompanying drawings, in which:

FIGS. 1 to 7 are cross-sectional views illustrating methods of manufacturing a PMOS transistor in accordance with some embodiments of the present invention;

FIGS. 8 to 17 are cross-sectional views illustrating methods of manufacturing a CMOS transistor in accordance with some embodiments of the present invention;

FIGS. 18 to 21 are cross-sectional views illustrating methods of manufacturing a CMOS transistor in accordance with some embodiments of the present invention;

FIGS. 22 and 23 are cross-sectional views illustrating methods of manufacturing a CMOS transistor in accordance with some embodiments of the present invention;

FIGS. 24 and 25 are cross-sectional views illustrating methods of manufacturing a CMOS transistor in accordance with some embodiments of the present invention;

FIGS. 26 to 28 are cross-sectional views illustrating methods of manufacturing a CMOS transistor in accordance with example some of the present invention;

FIG. 29 is a graph illustrating saturation currents and turn-off currents of PMOS transistors according to an Example 1 and a comparative example;

FIG. 30 is a graph illustrating saturation currents and turn-off currents of NMOS transistors according to an Example 1 and a comparative example;

FIG. 31 is a graph illustrating saturation currents and turn-off currents of PMOS transistors according to an Example 2 and a comparative example; and

FIG. 32 is a graph illustrating saturation currents and turn-off currents of NMOS transistors according to an Example 2 and a comparative example.

### DESCRIPTION OF EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary Methods of Manufacturing Transistors

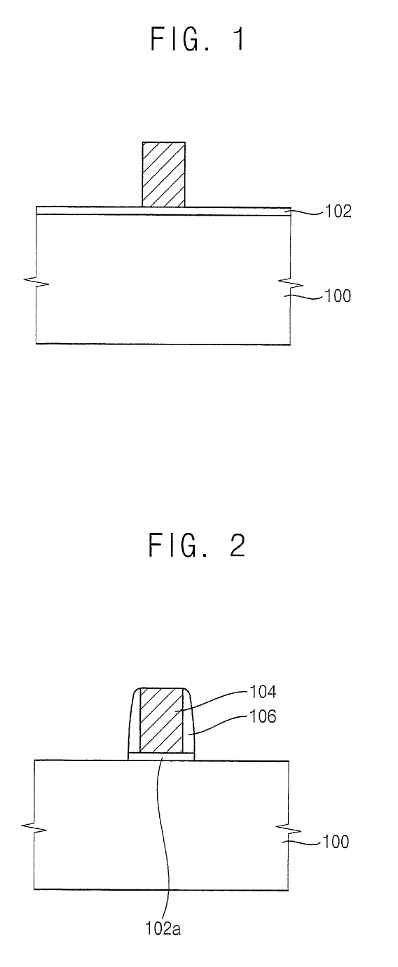

FIGS. 1 to 7 are cross-sectional views illustrating methods of manufacturing a PMOS transistor in accordance with some embodiments of the present invention. Although the methods described in the context of manufacturing a PMOS transistor, the features and possible advantages of the present invention can be employed in manufacturing other types of transistors, such as an N type MOS (NMOS) transistor and other field effect transistors.

Referring to FIG. 1, a substrate 100 including a semiconductor material is provided. The substrate 100 may include a single crystalline silicon substrate, a single crystalline germanium substrate, a silicon-on-insulator (SOI) substrate, a germanium-on-insulator (GOI) substrate, etc. In some example embodiments, the substrate 100 may include a silicon substrate that has a single crystalline structure of (1 0 0).

First impurities are doped into the substrate 100. The first impurities may have a first conductivity. For example, when the first impurities have an N type conductivity, the first impurities may include at least one of arsenic (As), phosphorus (P), antimony (Sb), etc. When the first impurities having the N type conductivity are doped into the substrate 100, the substrate 100 also has an N type conductivity. Alternatively, the substrate 100 may have a P type conductivity when the first impurities have a P type conductivity.

An isolation process is performed on the substrate 100 to form an isolation layer (not illustrated) on the substrate 100. An active region and a field region of the substrate 100 are defined by a formation of the isolation layer. For example, the isolation layer may be formed by an isolation process such as a shallow trench isolation (STI) process.

A gate insulation layer 102 is formed on the substrate 100. The gate insulation layer 102 may be formed using an oxide or a metal compound. For example, the gate insulation layer 102 may be formed using at least one of silicon oxide, hafnium oxide (HfOx), zirconium oxide (ZrOx), aluminum oxide (AlOx), tantalum oxide (TaOx), etc. The gate insulation layer 102 may be formed using at least one of a thermal oxidation process, a chemical vapor deposition (CVD) process, an atomic layer deposition (ALD) process, etc.

A first conductive layer (not illustrated) is formed on the gate insulation layer 102. The first conductive layer may be formed using polysilicon, polysilicon doped with impurities, a metal, and/or a metal compound. For example, the first conductive layer may be formed using at least one of tungsten (W), tungsten nitride (WNx), tungsten silicide (WSix), titanium (Ti), titanium nitride (TiNx), titanium silicide (TiSix), aluminum (Al), aluminum nitride (AlNx), tantalum (Ta), tantalum nitride (TaNx), tantalum silicide (TaSix), cobalt silicide (CoSix), etc. In some example embodiments, the first conductive layer may be formed using polysilicon without impurities.

After a mask (not illustrated) is formed on the first conductive layer, the first conductive layer is etched using the mask to form a gate electrode 104 on the gate insulation layer 102. The gate electrode 104 may be formed by an anisotropic etching process. After a formation of the gate electrode 104, the mask may be removed from the gate electrode 104.

Referring to FIG. 2, an insulation layer (not illustrated) is formed on the gate insulation layer 102 and covering the gate electrode 104. The insulation layer may be formed using a nitride or an oxynitride. For example, the insulation layer may be formed using silicon nitride or silicon oxynitride. Additionally, the insulation layer may be formed using at least one of a CVD process, a plasma enhanced chemical vapor deposition (PECVD) process, a low pressure chemical vapor deposition (LPCVD) process, etc.

The insulation layer and the gate insulation layer 102 are etched to form a spacer 106 and a gate insulation layer pattern 102a. The spacer 106 and the gate insulation layer pattern 102a may be formed by an anisotropic etching process. The spacer 102 is formed on a sidewall of the gate electrode 104, and the gate insulation layer pattern 102a is formed between the substrate 100 and the gate electrode 104. When the spacer 106 is formed on the sidewall of the gate electrode 104, a gate structure having the gate electrode 104, the gate insulation layer pattern 102a and the spacer 106 is provided on the substrate 100. After a formation of the spacer 106, an upper face of the gate electrode 104 is exposed.

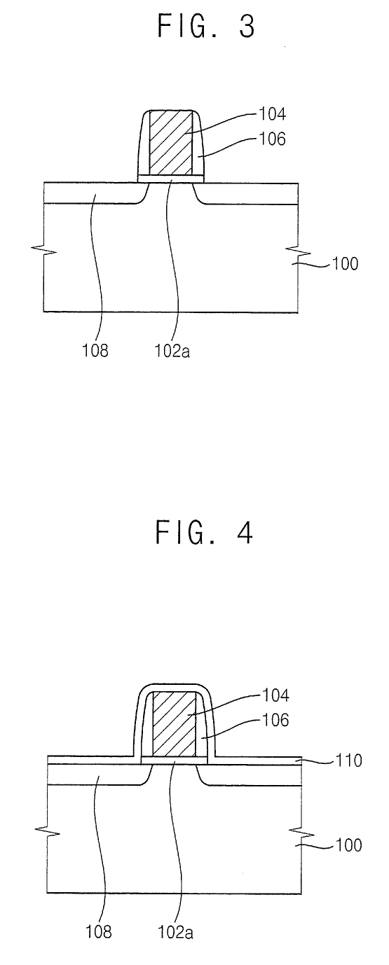

Referring to FIG. 3, a de-crystallization ion implantation process is performed on the gate electrode 104 and portions of the substrate 100 adjacent to the gate electrode 104. In example embodiments, second impurities are doped into the gate electrode 104 and the portions of the substrate 100. The second impurities may include at least one of germanium (Ge), xenon (Xe), carbon (C), fluorine (F), etc. In the de-crystallization ion implantation process, the portions of the substrate 100 and an upper portion of the gate electrode 104 may be de-crystallized. That is, the portions of the substrate 100 and the upper portion of the gate electrode 104 may both be changed to have amorphous crystalline structures. As a result, excessive lateral diffusion of impurities may be effectively prevented while carrying out a successive ion implantation process to form source/drain regions 108.

Third impurities having a second conductivity are doped into the upper portion of the gate electrode 104 and the portions of the substrate 100 adjacent to the spacer 104. The third impurities may have a P type conductivity. For example, the third impurities may include at least one of boron (B), boron fluoride (BFx)₇ gallium (Ga), indium (In), etc. When the third impurities are doped into the portions of the substrate 100, the portions of the substrate 100 are changed into source/drain regions 108 positioned adjacent to the gate electrode 104. Further, the third impurities may adjust a work function of the gate electrode 104 to reduce a resistance of the gate electrode 104.

In some further embodiments, the de-crystallization ion implantation process may be carried out before doping of the third impurities. Since the portions of the substrate 100 may have the amorphous crystalline structures, the third impurities may not be excessively diffused along a direction substantially parallel to the substrate 100. Hence, the transistor may thereby have a sufficient channel length because of the reduction/prevention of lateral diffusion of the third impurities.

Referring to FIG. 4, an oxide layer 110 is formed on the substrate 100, the spacer 106, and the gate electrode 104. That is, the oxide layer 110 is formed on the substrate 100 and covers the gate electrode 104 and the spacer 106. The oxide layer 110 may be conformally formed on the substrate 100, the spacer 106, and the gate electrode 104. The oxide layer 110 may be formed using silicon oxide by at least one of a thermal CVD process, a PECVD process, an LPCVD process, a high density plasma-chemical vapor deposition (HDP-CVD) process etc. The oxide layer 110 may include a tensile strained silicon oxide layer having a tensile stress generated therein, or a compressive strained silicon oxide layer having a compressive stress therein. Here, the tensile strained silicon oxide layer may have a tensile stress of about 0.05 GPa/cm2 to about 0.3 GPa/cm2 whereas the compressive strained silicon oxide layer may have a compressive stress of about −0.05 GPa/cm2 to about −0.3 GPa/cm2.

In some further embodiments, the tensile strained silicon oxide layer may be formed by the thermal CVD process using ozone (O3). The tensile strained silicon oxide layer may include tetraethylorthosilicate (TEOS). Alternatively, the compressive strained oxide layer may be formed by the PECVD process and/or the HDP-CVD process.

The oxide layer 110 may serve as a blocking layer that prevents a diffusion of the third impurities such as boron (B). When the oxide layer 110 includes the tensile strained silicon oxide layer, the diffusion of the third impurities may be more effectively prevented and improved electrical characteristics of the transistor may be ensured. Therefore, the oxide layer 110 may advantageously include the tensile strained silicon oxide layer containing O3-TEOS.

When the oxide layer 110 is formed at a temperature below about 350° C., the oxide layer 110 may not be properly formed by the thermal CVD process. When the oxide layer 110 is formed at a temperature above about 500° C., the portions of the substrate 100 and the upper portion of the gate electrode 104 may be re-crystallized. Therefore, the oxide layer 110 may be advantageously formed at one or more temperatures in a range between about 350° C. and about 500° C.

When the oxide layer 110 has a thickness below about 50 Å, the oxide layer 110 may not sufficiently protect the substrate 100, the gate electrode 104, and the spacer 106 in a successive etching process. When a thickness of the oxide layer 110 is above about 300 Å, the stress therein may not have the desired effect on a channel region of the transistor. Therefore, the oxide layer 110 may advantageously have a thickness in a range between about 50 Å and about 300 Å.

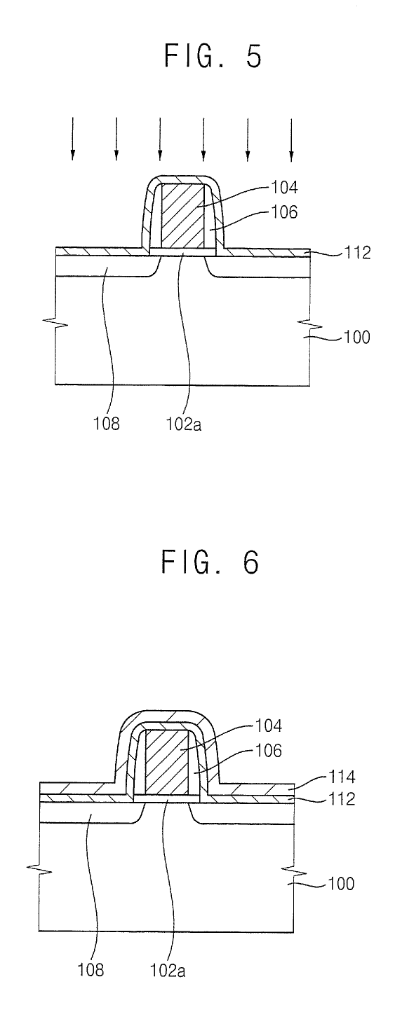

Referring to FIG. 5, the oxide layer 110 is changed into a diffusion preventing layer 112. In some further embodiments, the oxide layer 110 may be treated with a plasma to form the diffusion preventing layer 112. The plasma may be generated from at least one of an inactive gas, a hydrogen gas, an oxygen gas, an ozone gas, etc. Examples of the inactive gas may include a nitrogen gas, a helium gas, an argon gas, etc.

In some further embodiments, the oxide layer 110 may have a more dense structure and groups of —OH and —H included in the oxide layer 110 may be reduced through a use of the plasma treatment. The third impurities having the P type may not be easily diffused through the diffusion preventing layer 112 formed by the plasma treatment. In other words, an energy of the third impurities required to diffuse through the diffusion preventing layer 112 may be increased. Therefore, the diffusion preventing layer 112 may inhibit the third impurities from diffusing along the direction parallel to the substrate 100 and into an upper layer formed on the diffusion preventing layer 112.

In an exemplary embodiment, when the oxide layer 110 including O₃-TEOS is formed by the thermal CVD process, an amount of the groups of —OH in the oxide layer 110 may be increased. In another exemplary embodiment, when the oxide layer 110 including O₃-TEOS is formed by the plasma treatment, the amount of the groups of —OH in the oxide layer 110 may be decreased. In still another exemplary embodiment, when oxide layer 110 including O₃-TEOS is formed by the plasma treatment using oxygen (O₂) or ozone (O₃), the oxide layer 110 may have a more dense structure because a bond between —H and —OH may be enhanced.

When the plasma treatment is performed at a temperature below about 300° C., the oxide layer 110 may be insufficiently changed into the diffusion preventing layer 112. When the plasma treatment is performed at a temperature above about 700° C., a heat budget may be generated in the resultant structure and also the gate electrode 104 and the source/drain regions 108 having the non-crystalline structures may be re-crystallized. Therefore, the plasma treatment may be advantageously carried out at one or more temperatures between about 300° C. and about 700° C.

When the plasma treatment is carried out with a duration below about 3 minutes, the oxide layer 110 may not be sufficiently changed into the diffusion preventing layer 112. When the plasma treatment is carried out with a duration above about 5 minutes, the diffusion preventing layer 112 may be damaged by the plasma and a processing time may be increased. Therefore, the plasma treatment may be carried out with a duration from about 3 minutes to about 5 minutes.

Referring to FIG. 6, a nitride layer 114 is formed on the diffusion preventing layer 112 to form the channel region having a stress. For example, the nitride layer 114 may be formed using silicon nitride. In some embodiments, the nitride layer 114 may have a tensile stress. For example, the nitride layer 114 may have a tensile stress of about 0.80 GPa/cm2 to about 2.0 GPa/cm2. The tensile nitride layer 114 may be formed by a PECVD process, an HDP-CVD, etc.

When the nitride layer 114 has a thickness below about 100 Å, the tensile stress may not be sufficiently generated in the channel region because the nitride layer 114 is too thin. That is, the channel region of the transistor may not have a desired tensile stress. When a thickness of the nitride layer 114 is above about 1,000 Å, the thickness of the nitride layer 114 may be substantially thicker than that of the gate electrode 104 and such a thick nitride layer 114 may not be completely removed in a successive etching process, and the tensile stress in the channel region may not be increased. Thus, the nitride layer 114 may have a thickness in a range between about 100 Å and about 1,000 Å.

When the nitride layer 114 is formed at a temperature below about 300° C., the nitride layer 114 may not be properly formed on the diffusion preventing layer 112. When the nitride layer 114 is formed at a temperature above about 500° C., the non-crystallized portions may be undesirably re-crystallized. Hence, the nitride layer 114 may be formed at one or more temperatures in a range between about 300° C. and about 500° C.

In some further embodiments, when the nitride layer 114 is formed using a plasma, the process for forming the diffusion preventing layer 112 and the process for forming the nitride layer 114 may be carried out in-situ in a chamber without breaking vacuum seal. For example, when the nitride layer 114 is formed by the PECVD process, the plasma treatment for forming the diffusion preventing layer 112 and the PECVD process may be carried out in-situ.

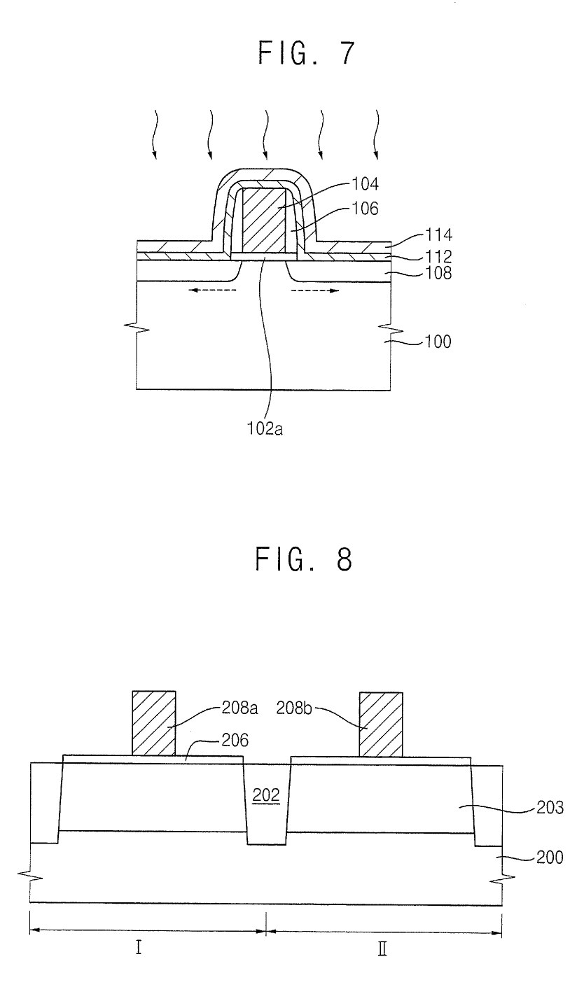

Referring to FIG. 7, a thermal process is performed on the substrate 100 having the nitride layer 114 to activate the third impurities included in the source/drain regions 108. For example, the substrate 100 may be thermally treated by a rapid thermal process. In example embodiments, the rapid thermal process may be performed at one or more temperatures in a range between about 900° C. and about 1,200° C. using a reaction gas including at least one of an inactive gas, a hydrogen gas, etc. Examples of the inactive gas may include at least one of a nitrogen (N₂) gas, a helium (He) gas, an argon (Ar) gas, etc.

In some further embodiments, the tensile stress of the nitride layer 114 may be further increased through the thermal process. When the nitride layer 114 has the increased tensile stress, the gate electrode 104 may have a further increased compressive stress. Therefore, the channel region positioned beneath the gate electrode 104 may have a further increased tensile stress.

In some further embodiments, the nitride layer 114 and the diffusion preventing layer 112 may be removed by an etching process. For example, nitride layer 114 and the diffusion preventing layer 112 may be removed by a wet etching process using an etching solution. The etching solution may include a phosphoric acid.

According to some further embodiments, the diffusion preventing layer 112 formed on the source/drain regions 108 may at least substantially inhibit or prevent the lateral diffusion of the third impurities such as boron B included in the source/drain regions 108 though the diffusion preventing layer 112 while activating the third impurities in the thermal process. Thus, a concentration of the third impurities in the source/drain regions 108 may not be decreased during manufacturing so as to ensure a low resistance of the source/drain regions 108. As a result, a saturation current of the transistor with the source/drain regions 108 may increase as a result of the diffusion preventing layer 112.

According to some further embodiments, the diffusion preventing layer 112 positioned on the gate electrode 104 may at least substantially inhibit or prevent the upward diffusion of the third impurities included in the gate electrode 104 though the diffusion preventing layer 112 while activating the third impurities in the thermal process. Hence, a concentration of the third impurities in the gate electrode 104 may not be reduced during manufacturing. When a voltage is applied to the gate electrode 104, a depletion region formed adjacent the gate electrode 104 may be decreased and an electrical thickness of the gate insulation layer pattern 102a may also be reduced. Further, a density of charge carriers in the channel region may increase and a density of a current of the transistor may also increase. As a result, the saturation current of the transistor including the gate electrode 104 may be considerably increased.

When the channel region positioned beneath the gate electrode 104 has the tensile stress, a gate on-current of the transistor may decrease. Thus, the transistor formed on the substrate 100 having the tensile stress may have a lower electrical gate current then the transistor formed on the substrate 100 having the compressive stress. The saturation current of the transistor may effectively increase because the diffusion of the third impurities in the gate electrode 104 and the source/drain regions 108 may be substantially inhibit/prevented as described above. The transistor may thereby have improved electrical characteristics.

FIGS. 8 to 17 are cross-sectional views illustrating methods of manufacturing a CMOS transistor in accordance with some embodiments of the present invention.

Referring to FIG. 8, a substrate 200 including a semiconductor material is prepared. The substrate 200 may include a single crystalline silicon substrate, a single crystalline germanium substrate, an SOI substrate, a GOI substrate, etc. In some example embodiments, the substrate 200 may include a single crystalline silicon substrate that has a crystalline structure of (1 0 0). The substrate 200 may have a first area I and a second area II. In an exemplary embodiment, an N type MOS (NMOS) transistor and a P type MOS (PMOS) transistor may be formed in the first area I and the second area II, respectively.

An isolation process is performed on the substrate 200 to form an isolation layer pattern 202 on the substrate 200. An active region and a field region of the substrate 200 may be defined by the formation of the isolation layer pattern 202. For example, the isolation layer pattern 202 may be formed by a shallow trench isolation (STI) process.

First impurities are doped into a first portion of the first area I and second impurities are doped into a second portion of the second area II to provide a first channel region in the first area I and a second channel region in the second area II, respectively. The first impurities may have a first conductivity whereas the second impurity may have a second conductivity opposite to the first conductivity. When the first impurities are P type, the second impurities are N type. For example, the first impurities may include at least one of boron (B), boron fluoride (BFx), gallium (Ga), indium (In), etc. The second impurities may include at least one of arsenic (As), phosphorus (P), antimony (Sb), etc.

In some further embodiments, after a first mask (not illustrated) exposing the first area I of the substrate 200 is formed on the substrate 200, the first impurities may be doped into the first portion of the first area I using the first mask as an ion implantation mask. After removing the first mask from the substrate 200, a second mask (not illustrated) exposing the second area II of the substrate 200 may be formed on the substrate 200. The second impurities may be doped at the second portion of the second area II using the second mask as an ion implantation mask. Then, the second mask may be removed from the substrate 200. For example, the first and the second mask may be formed using photoresist.

Referring still to FIG. 8, a gate insulation layer 206 is formed on the substrate 200 having the first and the second areas I and II. The gate insulation layer 206 may be formed using an oxide or a metal compound. For example, the gate insulation layer 206 may be formed using silicon oxide, hafnium oxide (HfOx), zirconium oxide (ZrOx), aluminum oxide (AlOx), tantalum oxide (TaOx), etc. Further, the gate insulation layer 206 may be formed by a thermal oxidation process, a CVD process, an ALD process, etc.

A first conductive layer (not illustrated) is formed on the gate insulation layer 206. The first conductive layer may be formed using polysilicon, polysilicon doped with impurities, a metal and/or a metal compound. For example, the first conductive layer may be formed using tungsten (W), tungsten nitride (WNx), tungsten silicide (WSix), titanium (Ti), titanium nitride (TiNx), titanium silicide (TiSix), aluminum (Al), aluminum nitride (AlNx), tantalum (Ta), tantalum nitride (TaNx), tantalum silicide (TaSix), cobalt silicide (CoSix), etc. These may be used alone or in a mixture thereof. In example embodiments, the first conductive layer may be formed using polysilicon containing no impurities.

A third mask (not illustrated) is formed on the first conductive layer. The third mask may be formed using a nitride such as silicon nitride. The first conductive layer is partially etched using the third mask as an etching mask to form a first gate electrode 208a and a second gate electrode 208b on the gate insulation layer 206. The first gate electrode 208a is formed in the first area I and the second gate electrode 208b is positioned in the second area II.

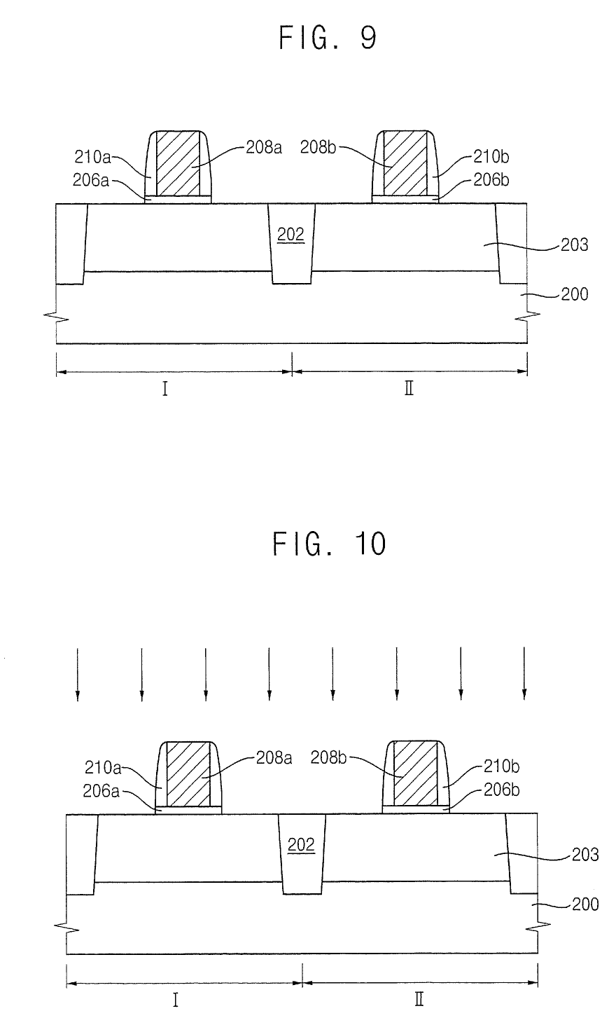

Referring to FIG. 9, an insulation layer (not illustrated) is formed on the gate insulation layer 205 and covers the first and the second gate electrodes 208a and 208b. The insulation layer may be formed using a nitride or an oxynitride. For example, the insulation layer may be formed using silicon nitride or silicon oxynitride. Additionally, the insulation layer may be formed by at least one of a CVD process, a PECVD process, an LPCVD process, etc.

The insulation layer and the gate insulation layer 205 are etched to form a first spacer 210a, a second spacer 210b, a first gate insulation layer pattern 206a, and a second gate insulation layer pattern 206b. For example, the insulation layer and the gate insulation layer 205 may be etched by an anisotropic etching process. The first spacer 210a is formed on a sidewall of the first gate electrode 208a, and the first gate insulation layer pattern 206a is positioned between the substrate 200 and the first gate electrode 208a. The second spacer 210b is formed on a sidewall of the second gate electrode 208b, and the second gate insulation layer pattern 206b is positioned between the substrate 200 and the second gate electrode 208b.

After forming the first and the second spacers 210a and 210b and the first and the second gate insulation layer patterns 206a and 206b, the third mask may be removed from the first and the second gate electrode 208a and 208b, thereby exposing upper faces of the first and the second gate electrodes 208a and 208b. When the first and the second spacers 210a and 210b and the first and the second gate insulation layer patterns 206a and 206b are formed, a first gate structure and a second gate structure are provided on the substrate 200. The first gate structure in the first area I includes the first gate insulation layer pattern 206a, the first gate electrode 208a and the first spacer 210a. The second gate structure in the second area II includes the second gate insulation layer pattern 206b, the second gate electrode 208b and the second spacer 210b.

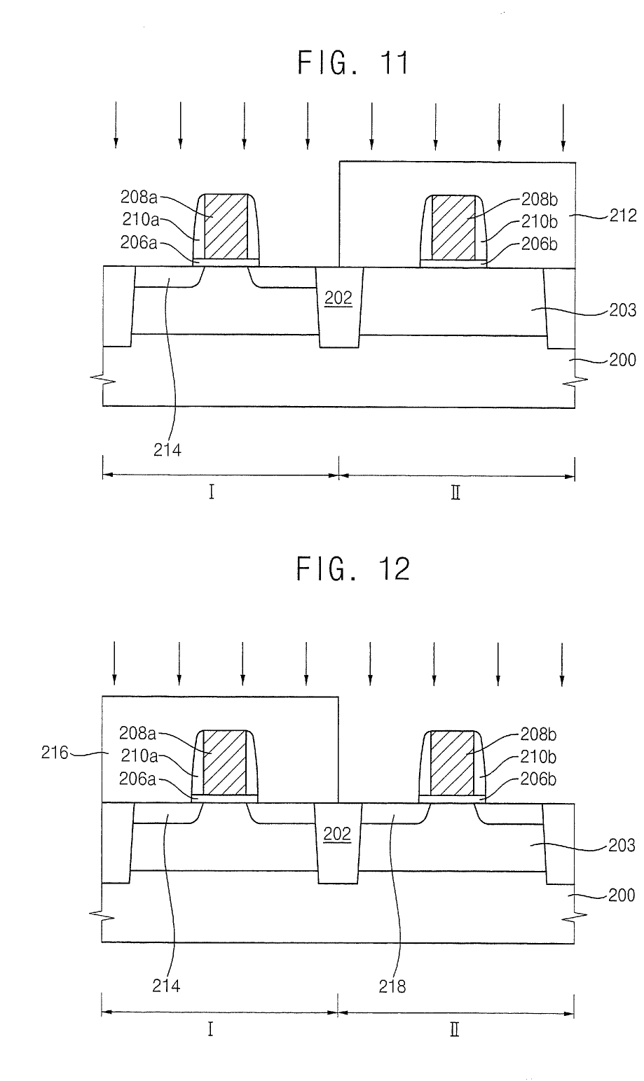

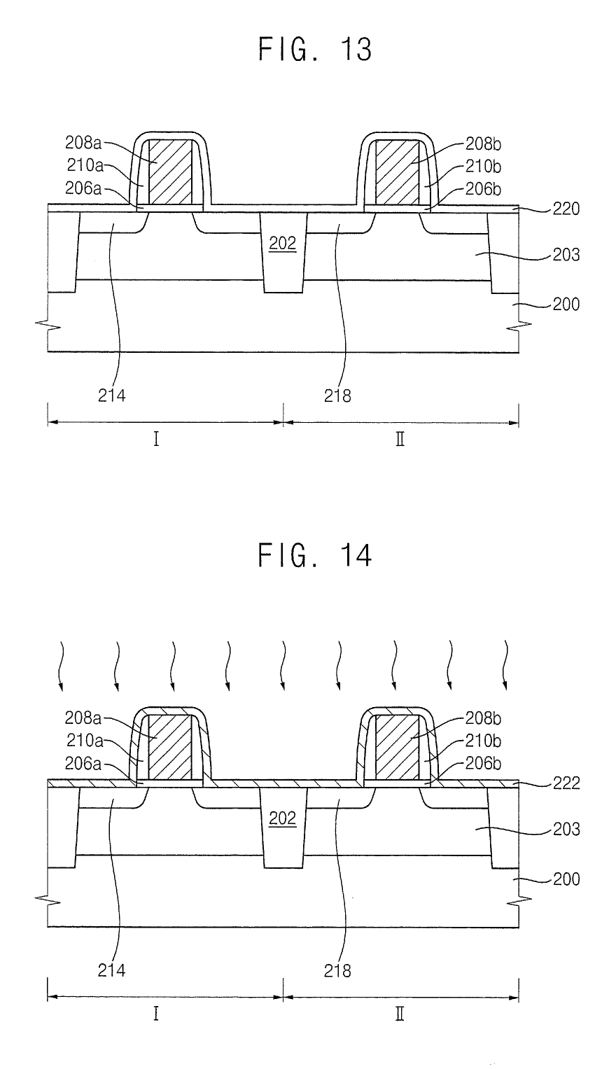

Referring to FIG. 10, a de-crystallization ion implantation process is performed on the first and the second gate electrodes 208a and 208b. The de-crystallization ion implantation process is also executed on portions of the first and the second areas I and II of the substrate 200. The defined portions of the first and the second areas I and II are adjacent to the first and the second gate electrodes 210a and 210b, respectively. In some further embodiments, third impurities are doped into the first and the second gate electrodes 208a and 208b as well as the portions of the first and the second areas I and II. The third impurities may include at least one of germanium (Ge), xenon (Xe), carbon (C), fluorine (F), etc. In the de-crystallization ion implantation process, the portions of the first and the second areas I and II and upper portions of the first and the second gate electrodes 208a and 208b may be non-crystallized. Namely, the portions of the substrate 200 and the upper portions of the first and the second gate electrodes 208a and 208b may each have amorphous crystalline structures. Hence, excessive lateral diffusion of impurities may be substantially inhibited or prevented during an ion implantation/anneal process that forms first and second source/drain regions 214 and 218 (see FIGS. 11 and 12).

Referring to FIG. 11, a fourth mask 212 exposing the first area I of the substrate 200 is formed on the substrate 200. The fourth mask 212 may be formed using a photoresist.

Fourth impurities of an N type are doped into first portions of the first area I adjacent to the first gate structure. The fourth impurities may include at least one of arsenic (As), phosphorus (P), antimony (Sb), etc. When the fourth impurities are doped into the first portions of the substrate 200, the first portions the substrate 200 are changed into the first source/drain regions 214. Further, the fourth impurities having the N type are doped into the first gate electrode 208a to adjust a work function of the first gate electrode 208a, thereby reducing a resistance of the first gate electrode 208a. After forming the first source/drain regions 214, the fourth mask 212 may be removed from the substrate 200.

Referring to FIG. 12, a fifth mask 216 exposing the second area II of the substrate 200 is formed on the substrate 200. The fifth mask 216 may be formed using a photoresist.

Fifth impurities of a P type are doped into second portions of the second area II of the substrate 200 adjacent to the second gate structure using the fifth mask as an ion implanting mask. The fifth impurities may include at least one of boron (B), boron fluoride (BFx), gallium (Ga), indium (In), etc. When the fifth impurities are doped into the second portions of the substrate 200, the second portions of the substrate 200 are changed into the second source/drain regions 218b adjacent to the second gate electrode 208b. Additionally, the fifth impurities having the P type are doped into the second gate electrode 208b so as to adjust a work function of the second gate electrode 208b. Thus, the second gate electrode 208b may have a reduced resistance.

Referring to FIG. 13, an oxide layer 220 is formed on the substrate 200 to cover the first and the second gate structures. The oxide layer 220 may be conformally formed on the substrate 200, the first spacer 210a, the first gate electrode 208a, the second spacer 210b, and the second gate electrode 208b. The oxide layer 110 may be formed using silicon oxide by a CVD process, a PECVD process, an LPCVD process, an HDP-CVD process etc. The oxide layer 220 may include a tensile strained silicon oxide layer having a tensile stress generated therein, or a compressive strained silicon oxide layer having a compressive stress therein. Here, the tensile strained silicon oxide layer may have a tensile stress of about 0.05 GPa/cm2 to about 0.3 GPa/cm2, whereas the compressive strained silicon oxide layer may have a compressive stress of about −0.05 GPa/cm2 to about −0.3 GPa/cm2.

In some further embodiments, the tensile strained silicon oxide layer may be formed by a thermal CVD process using ozone (O3). For example, the tensile strained silicon oxide layer may include tetraethylorthosilicate (TEOS). Alternatively, the compressive strained silicon oxide layer may be formed by a PECVD process and/or an HDP-CVD process. The oxide layer 220 may be formed at one or more temperatures in a range between about 350° C. and about 500° C. The oxide layer 110 may have a thickness in a range between about 50 Å and about 300 Å.

Referring to FIG. 14, the oxide layer 220 is changed into a diffusion preventing layer 222 by a plasma treatment. The diffusion preventing layer 222 may be formed using a plasma generated from at least one of an inactive gas, a hydrogen gas, an oxygen gas, an ozone gas, etc. Examples of the inactive gas may include a nitrogen gas, a helium gas, an argon gas, etc.

In some further embodiments, the diffusion preventing layer 222 may have a more dense structure and groups of —OH and —H included in the diffusion preventing layer 220 may be reduced through the plasma treatment. Thus, the fifth impurities of the P type may not be easily diffused through the diffusion preventing layer 222, because an energy required for the fifth impurities to diffuse through the diffusion preventing layer 222 may be increased. Therefore, the fifth impurities may not upwardly and horizontally diffuse because of the diffusion preventing layer 222. When the oxide layer 220 including O₃-TEOS is formed by the thermal CVD process, an amount of the groups of —OH included in the oxide layer 220 may increase. However, the oxide layer 220 including O₃-TEOS is formed by the PECVD process, the amount of the groups of —OH included in the oxide layer 220 may decrease. When the oxide layer 220 including O₃-TEOS is formed by a plasma treatment using oxygen (O2) or ozone (O3), the oxide layer 220 may have a more dense structure because a combination between —H and —OH may be enhanced.

In some further embodiments, the plasma treatment for forming the diffusion preventing layer 222 may be carried out at one or more temperatures in a range between about 300° C. and about 700° C. for a duration between about 1 minute to about 5 minutes. However, the process time of the plasma treatment may vary in response to the associated temperature and/or a thickness of the oxide layer 220.

Referring to FIG. 15, a nitride layer 224 is formed on the diffusion preventing layer 222 to cause stresses in a first channel region and in a second channel region. For example, the nitride layer 224 may be formed using silicon nitride. In some further embodiments, when the nitride layer 224 is formed to have a tensile stress, tensile stresses can be generated in the first and the second channel regions. Here, the nitride layer 224 may have a tensile stress of about 0.80 GPa/cm2 to about 2.0 GPa/cm2. This tensile nitride layer 224 may be formed by various CVD processes such as an LPCVD process, a PECVD process, an HDP-CVD, etc.

To form the nitride layer 224 having the tensile stress, the associated plasma process and/or the deposition speed may be adjusted. When the nitride layer 224 is formed by the CVD process, the tensile stress in the nitride layer 224 may increase as a direct current (DC) bias voltage applied to the substrate 200 is reduced and a deposition rate of the nitride layer 224 is lowered. When the nitride layer 224 is formed by the PECVD process, a reaction gas including silane (SiH₄) and ammonia (NH₃) may be employed.

In some further embodiments, the nitride layer 224 may be formed at one or more temperatures in a range between about 300° C. and about 700° C. to have a thickness in a range between about 1000 Å and about 1,000 Å.

When the nitride layer 224 is formed using the plasma, forming the diffusion preventing layer 222 and forming the nitride layer 224 may be executed in-situ (in a chamber without breaking vacuum seal). For example, the plasma treatment for the diffusion preventing layer 222 and the PECVD process for forming the nitride layer 224 may be performed in-situ when the nitride layer 114 is formed by the PECVD process.

During formation of the diffusion preventing layer 222 and the nitride layer 224, the substrate 200 having the oxide layer 220 may be loaded into a process chamber. After performing the plasma treatment for forming the diffusion preventing layer 222 in the process chamber, the nitride layer 224 may be continuously formed on the diffusion preventing layer 22 in the process chamber. When the plasma treatment for forming the diffusion preventing layer 222 and the formation process of the nitride layer 224 are executed in-situ, a processing time for the transistor may decrease whereas a productivity of the transistor may increase.

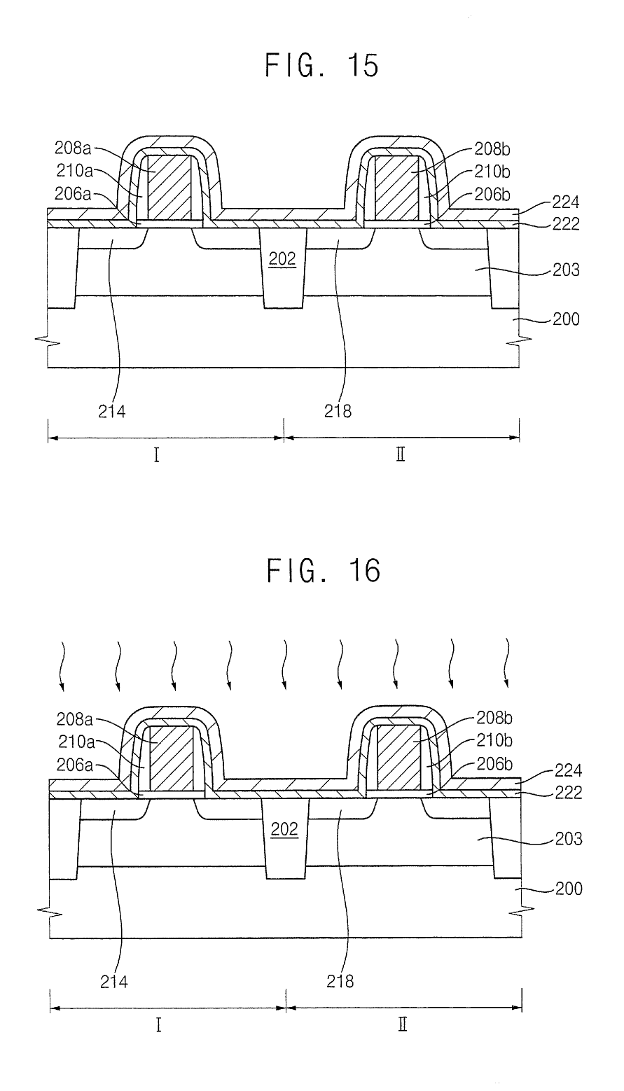

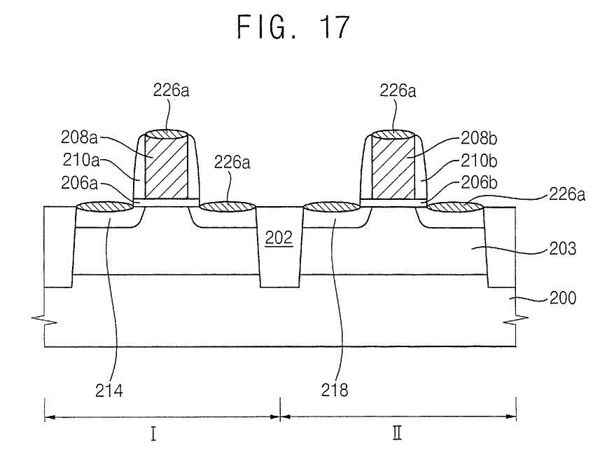

Referring to FIG. 16, a thermal process is carried out on the substrate 100 to activate the fourth and fifth impurities in the first and the second source/drain regions 214 and 218. For example, the thermal process may include a rapid thermal process. The tensile stress of the nitride layer 224 may be enhanced through the thermal process. When the nitride layer 224 has the enhanced tensile stress, compressive stresses may be caused in the first and the second gate electrodes 208a and 208b. Thus, the first and the second channel region positioned beneath the first and the second gate electrodes 208a and 208b may each be caused to have tensile stresses.

In some further embodiments, the substrate 200 may be thermally treated at one or more temperatures in a range between about 900° C. and about 1,200° C. using a reaction gas. The reaction gas may include at least one of an inactive gas, a hydrogen gas, etc. Examples of the inactive gas may include a nitrogen gas, a helium gas, an argon gas, etc.

In some example embodiments, the tensile nitride layer 224 is positioned in the first and the second areas I and II of the substrate 200 so that the first channel region of the NMOS transistor and the second channel region of the PMOS transistor may be formed to have the desired tensile stresses.

In the thermal process, the diffusion preventing layer 222 may substantially inhibit/prevent a lateral diffusion of the fifth impurities such as boron included in the second source/drain regions 218 while activating the fifth impurities. Hence, a concentration of the fifth impurities in the second source/drain 218 may increase whereas a resistance of the second source/drain regions 218 may decrease. As a result, a saturation current of the PMOS transistor having the second source/drain regions 218 may increase. Further, the diffusion preventing layer 222 may prevent an upward diffusion of the fifth impurities in the second gate electrode 208b so that a concentration of the fifth impurities in the second gate electrode 208b may increase. Thus, a depletion region adjacent the second gate electrode 208b may decrease and an electrical thickness of the second gate insulation layer pattern 206b may be thinner. A density of charge carriers in the second channel region may also increase. As a result, a saturation current of the PMOS transistor having the second gate electrode 208b may substantially increase. As the diffusion of the fifth impurities in the second gate electrode 208b and the second source/drain region 218 decreases, the saturation current of the PMOS transistor may substantially increase. Therefore, the PMOS transistor may have improved electrical characteristics although the second channel region has the tensile stress.

Referring to FIG. 17, the nitride layer 224 and the diffusion preventing layer 222 are removed by an etching process. For example, the nitride layer 224 and the diffusion preventing layer 222 may be removed by a wet etching process using an etching solution that includes a phosphoric acid solution.

A second conductive layer (not illustrated) is formed on the substrate 200 to cover the first and the second gate structures. For example, the second conductive layer may be conformally formed on the substrate 200, the first spacer 210a, the first gate electrode 208a, the second spacer 210b, and the second gate electrode 208b. The second conductive layer may be formed using a metal. For example, the second conductive layer may formed using at least one of titanium (Ti), tungsten (W), aluminum (Al), cobalt (Co), etc. The second conductive layer may serve as first and second metal silicide patterns 226a and 226b formed on the first source/drain region 214, the first gate electrode 208a, the second source/drain region 218, and the second gate electrode 208b.

A thermal process is performed on the second conductive layer to form the first and the second metal silicide patterns 226a and 226b. The first and the second metal silicide pattern 226a and 226b may be formed by reaction between metal in the second conductive layer and silicon in the substrate 200, the first gate electrode 208a and the second gate electrode 208b. A remaining portion of the second conductive layer that is not reacted with silicon may be removed from the substrate 200.

The first and the second metal silicide patterns 226a and 226b may decrease resistances of the first and the second source/drain regions 214 and 218 and the first and the second gate electrodes 208a and 208b. In some embodiments, formation of the first and the second metal silicide patterns 226a and 226b may be omitted to simplify manufacturing processes for forming the CMOS transistor.

According to some further embodiments, the CMOS transistor may be provided on the substrate 200 in which the first and the second channels having the tensile stresses are formed. Although the PMOS and the NMOS transistors are formed on the first and the second channels having the tensile stresses, the PMOS transistor may have improved electrical characteristics. Further, additional processes for generating the tensile stress in the second channel of the PMOS transistor may be omitted so that manufacturing processes for the CMOS transistor may be simplified.

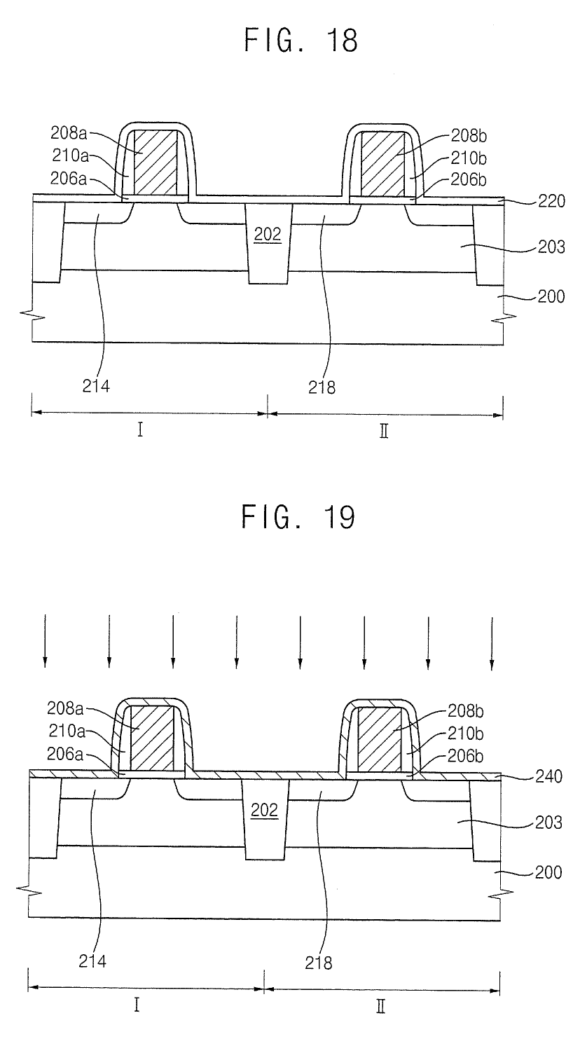

FIGS. 18 to 21 are cross-sectional views illustrating methods of manufacturing a CMOS transistor according to some embodiments of the present invention. The methods of manufacturing the CMOS transistor illustrated in FIGS. 18 to 21 may be substantially the same as or substantially similar to those described with reference to FIGS. 8 to 17 except for formation of a diffusion preventing layer 240. Further description of some of the processes for manufacturing the CMOS transistor will be omitted because they are substantially the same as or substantially similar to the above described processes illustrated in FIGS. 8 to 12.

Referring to FIG. 18, a first gate insulation layer pattern 206a, a first gate electrode 208a, a first spacer 210a, and first source/drain regions 214 are formed in a first area I of a substrate 200. Further, a second gate insulation layer pattern 206b, a second electrode 208b, a second spacer 210b, and second source/drain regions 218 are formed in a second area II of the substrate 200 as described above. That is, a first gate structure and a second gate structures are provided in the first and the second areas I and II.

An oxide layer 220 is formed on the substrate 200 to cover the first and the second gate structures. The oxide layer 220 may be conformally formed on the first and the second electrodes 208a and 208b, the first and the second spacers 210a and 210b, and the substrate 200. The oxide layer 220 may include a tensile strained silicon oxide layer having a tensile stress, or may include a compressive strained silicon oxide layer having a compressive stress. For example, the oxide layer 220 may have a tensile stress of about 0.05 GPa/cm2 to about 0.3 GPa/cm2 or a compressive stress of about −0.05 GPa/cm2 to about −0.3 GPa/cm2.

In some further embodiments, the tensile strained silicon oxide layer including tetraethylorthosilicate (TEOS) may be formed by a thermal CVD process using the assistance of ozone (O₃). Alternatively, the compressed oxide layer may be formed by a PECVD process and/or an HDP-CVD process.

Referring to FIG. 19, the oxide layer 220 is converted into a diffusion preventing layer 240. The diffusion preventing layer 240 may be formed by treating the oxide layer 220 with ultraviolet light. The ultraviolet light irradiating onto the oxide layer 220 may have a wavelength of about 100 nm to about 300 nm. For example, the ultraviolet may preferably have one or more wavelengths in a range between about 200 nm and about 300 nm. Further, the substrate 200 may be maintained in one or more temperatures in a range between about 300° C. and about 700° C. while carrying out the ultraviolet light irradiation for a duration of about 1 minute to about 5 minute.

When the duration of the ultraviolet light irradiation is below about 1 minute, the oxide layer 220 may not be sufficiently changed into the diffusion preventing layer 240. When the oxide layer 120 is treated for duration above about 5 minutes, the diffusion preventing layer 222 may be damaged by the ultraviolet light and a processing time thereof may be increased. Therefore, it may be advantageous for the ultraviolet light irradiation to be carried out for a duration in a range between about 1 minute and about 5 minutes.

In some further embodiments, the ultraviolet light irradiation for forming the diffusion preventing layer 240 may be carried out in an atmosphere that includes an inactive gas. Examples of the inactive gas may include a nitrogen gas, a helium gas, an argon gas, etc.

When the ultraviolet light is irradiated onto a surface of the oxide layer 220, molecular bonds in the oxide layer 220 may be broken by the ultraviolet light. For example, an amount of weak bonds of Si—OH, Si—H bonds or N—H bonds may be reduced in the oxide layer 220 because these weak bonds may be easily broken by the ultraviolet light. Therefore, bonds of Si—O in the diffusion preventing layer 240 may increase and groups of —OH and —H in the diffusion preventing layer 240 after the ultraviolet light irradiation. Energies of the fourth and the fifth impurities in the first and the second source/drain regions 214 and 218 required for them to diffuse through the diffusion preventing layer 240 may be increased. The fourth and the fifth impurities may not upwardly and laterally diffuse due to the formation of the diffusion preventing layer 240.

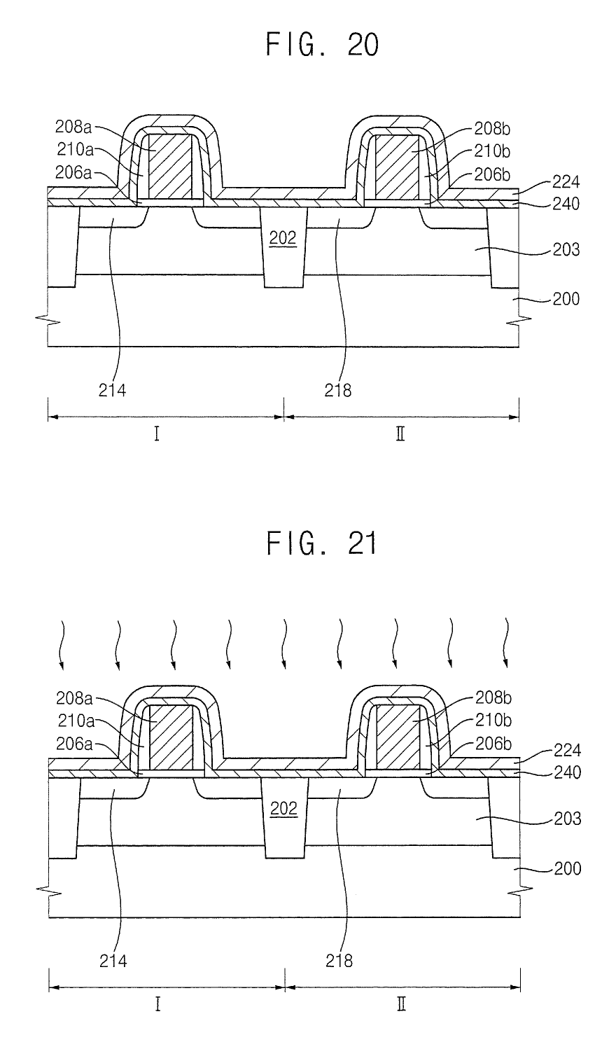

Referring to FIG. 20, a nitride layer 224 is formed on the diffusion preventing layer 240 to form a first channel region and a second channel region having stresses. For example, the nitride layer 224 may be formed using silicon nitride. In example embodiments, the first and the second channel regions may have tensile stresses when the nitride layer 224 has a tensile stress. For example, the nitride layer 224 may have a tensile stress of about 0.80 GPa/cm2 to about 2.0 GPa/cm2. This tensile nitride layer 224 may be formed by a PECVD process using a reaction gas including silane (SiH4), ammonia (NH3), etc. Further, the nitride layer 224 may be formed at one or more temperatures in a range between about 300° C. and about 700° C. to have a thickness in a range between about 100 Å and about 1,000 Å.

Referring to FIG. 21, a thermal process is carried out on the substrate 200 to activate the fourth and the fifth impurities included in the first and the second source/drain regions 214 and 218. The thermal process may include a rapid thermal process so that the tensile stress of the nitride layer 224 may be increased by the thermal process. When the nitride layer 224 has the increased tensile stress, the first and the second gate electrodes 208a and 208b may have compressive stresses. Thus, the first and the second channel regions positioned beneath the first and the second gate electrodes 208a and 208b may each have tensile stresses. That is, the nitride layer 224 having the tensile stress may be formed in the first and the second areas I and II of the substrate 200 so that the first channel region of the NMOS transistor and the second channel region of the PMOS transistor may each be subjected to the tensile stresses.

The nitride layer 224 and the diffusion preventing layer 222 may be removed by an etching process. Then, first and second metal silicide patterns 226a and 226b are formed on the first and the second source/drain regions 214 and 218, and the first and the second gate electrodes 208a and 208b. Detailed descriptions of processes for forming the first and the second metal silicide pattern 226a and 226b are omitted because they are substantially the same as or substantially similar to those already described with reference to FIG. 17.

According to some further embodiments, the diffusion of the fourth and the fifth impurities in the first and the second source/drain region 214 and 218 may be substantially inhibited/prevented due to the ultraviolet light irradiation. Thus, the manufacturing processes for forming the CMOS transistor may be simplified and the CMOS transistor may have a higher efficiency.

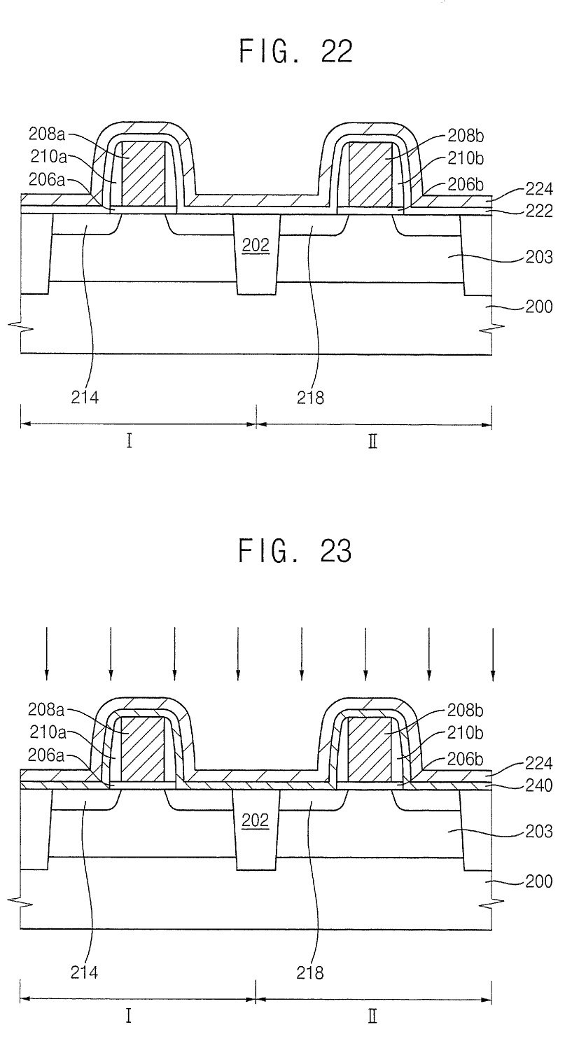

FIGS. 22 and 23 are cross-sectional views illustrating methods of manufacturing a CMOS transistor in accordance with some embodiments of the present invention. The methods of manufacturing the CMOS transistor illustrated in FIGS. 22 and 23 may be substantially the same as or substantially similar to the methods for manufacturing the CMOS transistor described with reference to FIGS. 18 to 21 except for an ultraviolet light irradiation. Detailed descriptions of the methods for manufacturing the CMOS transistor will be omitted because these are substantially similar to those already described with reference to FIG. 18.

Referring to FIG. 22, a first gate structure, a second gate structure, first source/drain regions 214 and second source/drain regions 218 are formed in a first area I and a second area II of a substrate 200. The first gate structure includes a first gate insulation layer pattern 206a, a first gate electrode 208a, and a first spacer 210a. The second gate structure has a second gate insulation layer pattern 206b, a second electrode 208b, and a second spacer 210b.

An oxide layer 222 is formed on the substrate 200 to cover the first and the second gate structures. This process may be substantially the same as or substantially similar to that described with reference to FIG. 18.

A nitride layer 224 is formed on the oxide layer 222 using silicon nitride to form a first channel region in the first area I and a second channel region in the second area II. The first and the second channel regions may be formed to have tensile stresses therein. The first and the second channel regions may have the tensile stresses because the nitride layer 224 has a tensile stress generated therein. The nitride layer 224 may have a tensile stress of about 0.80 GPa/cm2 to about 2.0 GPa/cm2.

In one example embodiment, the oxide layer 220 may be converted into a diffusion preventing layer 240 by a plasma treatment substantially similar to that described with reference to FIG. 14 before forming the nitride layer 224. In another example embodiment, the oxide layer 220 may be changed into a diffusion preventing layer 240 by an ultraviolet irradiation as shown in FIG. 19 before forming the nitride layer 224.

As illustrated in FIG. 23, the oxide layer 222 formed beneath the nitride layer 224 is changed into the diffusion preventing layer 240. That is, in some example embodiments, the oxide layer 222 is converted into the diffusion preventing layer 240 after a formation of the nitride layer 224.

When the oxide layer 222 is treated by an ultraviolet light irradiation for a duration of about 1 minute to about 5 minute, the substrate 200 may have a temperature of about 300° C. to about 700° C. Here, the diffusion preventing layer 240 may be formed by irradiating the ultraviolet light onto the oxide layer 220 in an atmosphere including an inactive gas such as a nitrogen gas, a helium gas, an argon gas, etc.

With the ultraviolet light irradiation, bonds of Si—O in the diffusion preventing layer 240 may increase and groups of —OH and —H in the oxide layer 222 may decrease. Thus, the diffusion preventing layer 240 may have a more dense structure. Electrical characteristics of the nitride layer 224 may be changed by the ultraviolet light irradiation. For example, bonds of molecules in the nitride layer 224 except for bonds of Si—N may be broken by the ultraviolet light and vacancies in the nitride layer 224 may be augmented. Accordingly, the tensile stress of the nitride layer 224 may be increased.

In some further embodiments, a thermal process for activating fourth and fifth impurities in the first and the second source/drain regions 214 and 218 may be performed on the substrate 200, and then, the nitride layer 224 and the diffusion preventing layer 240 may be removed from the substrate 200.

According to some further embodiments, upward and lateral diffusions of the fourth and the fifth impurities in the first and the second source/drain region 214 and 218 may be substantially inhibited/prevented by forming the diffusion preventing layer 240. Further, manufacturing processes for forming the CMOS transistor may be simplified and the CMOS transistor may have a high efficiency.

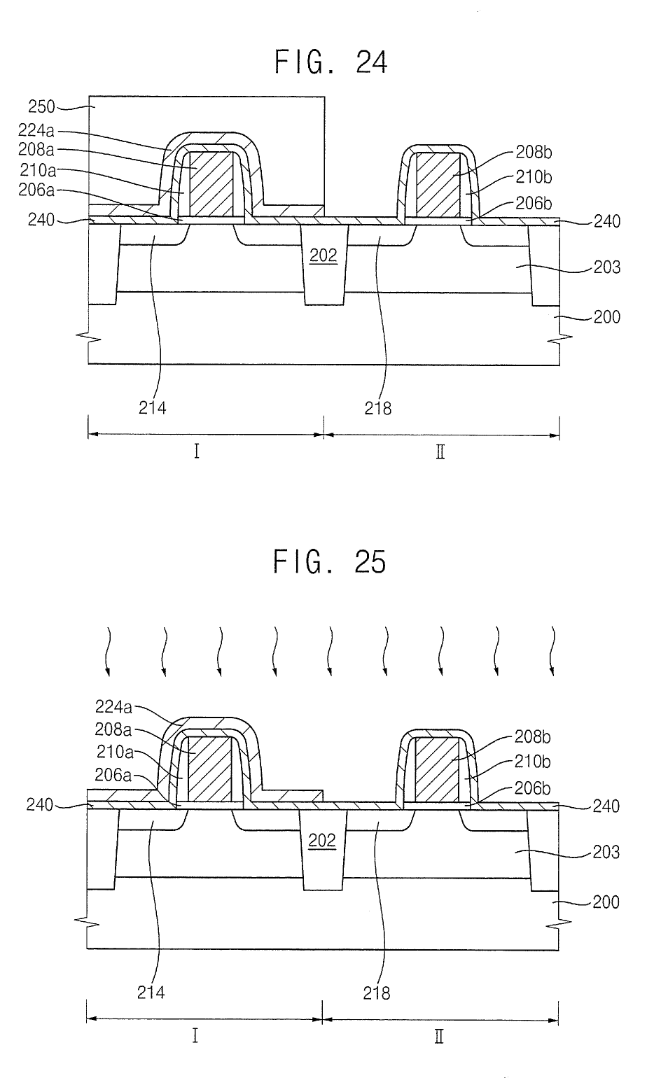

FIGS. 24 and 25 are cross-sectional views illustrating methods of manufacturing a CMOS transistor in accordance with some embodiments of the present invention. The methods of manufacturing the CMOS transistor illustrated in FIGS. 24 and 25 may be substantially the same as or substantially similar to the methods for manufacturing the CMOS transistor described with reference to FIGS. 22 and 23 except for an additional process for improving characteristics of a PMOS transistor. Detailed descriptions of the methods of manufacturing the CMOS transistor will be omitted because these are similar to those already described with reference to FIGS. 8 to 13.

Referring to FIG. 24, a first gate structure, a second gate structure, first source/drain regions 214 and second source/drain regions 218 are provided in a first area I and a second area II of a substrate 200. The first gate structure in the first area I has a first gate insulation layer pattern 206a, a first gate electrode 208a and a first spacer 210a. The second gate structure in the second area II includes a second gate insulation layer pattern 206b, a second electrode 208b and a second spacer 210b.

An oxide layer (not illustrated) is formed on the substrate 200 to cover the first and the second gate structures. The oxide layer may include a tensile silicon oxide layer or a compressive silicon oxide layer.

In an example embodiment, the oxide layer may be changed into a diffusion preventing layer 240 before forming a nitride layer (not illustrated) by a plasma treatment substantially similar to that described with reference to FIG. 14. In another example embodiment, the oxide layer may be converted into the diffusion preventing layer 240 before forming the nitride layer by an ultraviolet light irradiation substantially similar to that described with reference to FIG. 19.

The nitride layer is formed on the diffusion preventing layer 240 using silicon nitride. In some embodiments, tensile stresses may generate in a first channel region and a second channel region of the CMOS transistor when the nitride layer has a tensile stress.

Referring to FIG. 24, a photoresist film (not illustrated) is coated on the nitride layer. A photoresist pattern 250 film is formed on a first portion of the nitride layer in the first area I of the substrate 200 by patterning the photoresist film. That is, the photoresist pattern exposes a second portion of the nitride layer in the second area II where a PMOS transistor is positioned.

The nitride layer is partially etched using the photoresist pattern 250 as an etching mask to form a nitride layer pattern 224a in the first area I of substrate 200 where an NMOS transistor is positioned. In some embodiments, the nitride layer pattern 224a may be formed by a wet etching process so that underlying layers may not be damaged in the etching process.

After formation of the nitride layer pattern 224a, the photoresist pattern 250 may be removed by an ashing process and/or a stripping process.

Referring to FIG. 25, a thermal process including a rapid thermal process is performed about the substrate 200 having the nitride layer pattern 244a to activate impurities included in the first and second source/drain regions 214 and 218. The tensile stress of the nitride layer pattern 244a may be enhanced through the thermal process. When the nitride layer pattern 244a has an increased tensile stress, the first gate electrode 208a may have a compressive stress. Thus, the first channel region under the first gate electrode 208a may also have a tensile stress. The second channel region formed under the second gate electrode 208b may not have a tensile stress because the nitride layer is removed in the second area II of the substrate 200. Hence, charge carriers in the second channel region may increase and electrical characteristics of the PMOS transistor may be improved.

After thermal treating the substrate 200, the nitride layer pattern 224a and the diffusion preventing layer 222 may be removed from the substrate 200.

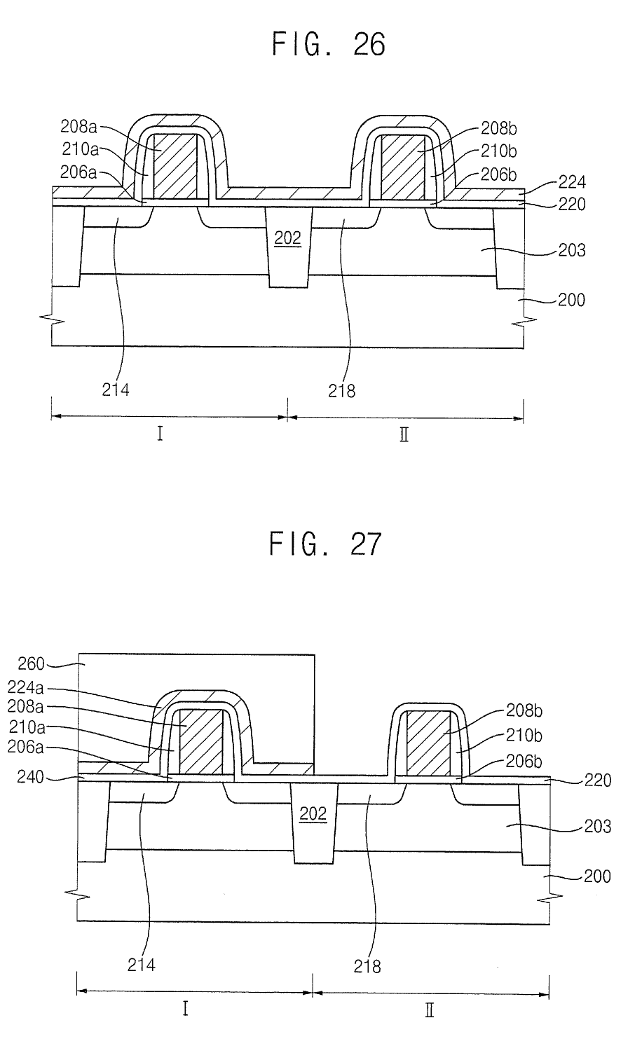

FIGS. 26 to 28 are cross-sectional views illustration methods of manufacturing a CMOS transistor in accordance with some embodiments of the present invention. The methods of manufacturing the CMOS transistor illustrated in FIGS. 26 to 28 may be substantially the same as or substantially similar to the methods of forming the CMOS transistor described with reference to FIGS. 18 to 13. Thus, detailed descriptions of the methods of manufacturing the CMOS transistor will be omitted because these are similar to those already described with reference to FIGS. 18 to 13.

Referring to FIG. 26, a first gate structure and first source/drain regions 214 are formed in a first area of a substrate 200, and a second gate structure and second source/drain regions 218 are provided in a second area II of the substrate 200. The first gate structure has a first gate insulation layer pattern 206a, a first gate electrode 208a and a first spacer 210a. The second gate structure includes a second gate insulation layer pattern 206b, a second electrode 208b and a second spacer 210b.

An oxide layer 220 is formed the substrate 200, the first gate structure and the second gate structure. The oxide layer 220 may be formed using silicon oxide. A nitride layer 224 is formed on the oxide layer 220 to generate tensile stresses in a first channel region and a second channel region. For example, the nitride layer 224 may be formed using silicon nitride to have a tensile stress of about 0.80 GPa/cm2 to about 2.0 GPa/cm2.

Referring to FIG. 27, after a photoresist film (not illustrated) is coated on the nitride layer 224, a photoresist pattern 250 exposing a portion of the nitride layer 224 in the second area II is formed on the nitride layer 224. A PMOS transistor is formed in the second area II.

An exposed portion of the nitride layer 224 is removed using the photoresist pattern 250 as an etching mask to form a nitride layer pattern 224a in the first area I of substrate 200 where an NMOS transistor is formed. In some embodiments, the nitride layer 224 may be etched by a wet etching process to preventing damages to underlying layers in the etching process. Then, the photoresist pattern 250 may be removed by an ashing process and/or a stripping process.

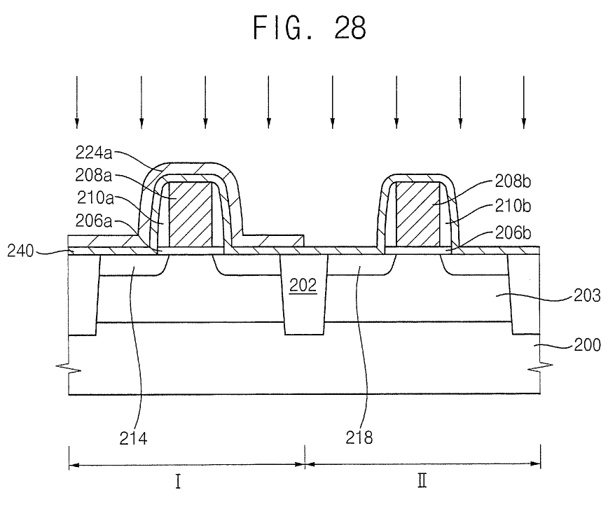

Referring to FIG. 28, the oxide layer 220 is converted into a diffusion preventing layer 240 by a plasma treatment and/or an ultraviolet light irradiation.

In example embodiments, a thermal process may be performed on the substrate 200 having the nitride layer pattern 224a to activate impurities included in the first and the second source/drain regions 214 and 218. Then, the nitride layer pattern 224a and diffusion preventing layer 222 may be removed from the substrate 200.

Hereinafter, various methods of manufacturing CMOS transistors according to the identified Examples and Comparative Example of various embodiments of the present invention and associated evaluation of electrical characteristics that may be obtained for the CMOS transistors will be described in detail.

### Example 1

A CMOS transistor was manufactured by processes substantially the same as or substantially similar to those described with reference to FIGS. 8 to 17.

After a single crystalline silicon substrate having a crystalline structure of (1 0 0) was prepared, a gate insulation layer and a polysilicon layer were formed on the substrate. The polysilicon layer and the gate insulation layer were partially etched to form a first gate structure of an NMOS transistor and a second gate structure of a PMOS transistor on the substrate. Each of the first and the second gate structures had a length of about 0.5 μm to about 0.6 μm and a width of about 5 μm.

Spacers were formed on sidewalls of the first and the second gate structures, and then N type impurities such as P were implanted into first portions of the substrate adjacent to the first gate structure to form first source/drain regions at the first portions of the substrate. P type impurities such as B were implanted into second portions of the substrate adjacent to the second gate structure to form second source/drain regions at the second portions of the substrate. A silicon oxide layer having a thickness of about 110 Å was formed on the substrate to cover the first and the second gate structures. A plasma treatment was performed about the silicon oxide layer using a nitrogen plasma. A PECVD process was performed to form a silicon nitride layer on the oxide layer. A thermal treatment was carried out on the substrate to provide a first channel region and a second channel region while activating the impurities. The first and the second channel regions had tensile stresses.

### Example 2

A CMOS transistor was manufactured by processes substantially the same as or substantially similar to those described with reference to FIGS. 8 to 17.

A single crystalline silicon substrate having a crystalline structure of (1 0 0) was provided, and then a gate insulation layer and a polysilicon layer were formed on the substrate. The polysilicon layer and the gate insulation layer were partially etched to form a first gate structure of an NMOS transistor and a second gate structure of a PMOS transistor on the substrate. The first and the second gate structures had lengths of about 0.5 to about 0.6 μm and widths of about 5 μm, respectively.

Spacers were formed on the sidewalls of the first and the second gate structure. N type impurities were implanted into first portions of the substrate adjacent to the first gate structure to form first source/drain regions. P type impurities were implanted into second portions of the substrate adjacent to the second gate structure to form second source/drain regions. A low temperature oxide layer having a thickness of about 110 Å was formed on the substrate to cover the first and the second gate structures. A plasma treatment was executed on the oxide layer using a hydrogen plasma. After a PECVD process was performed to form a silicon nitride layer, a thermal treatment was carried out to provide a first channel region and a second channel region while activating the impurities. The first and the second channel regions had tensile stresses.

### Comparative Example

To compare a performance of CMOS transistors according to Examples 1 and 2, a CMOS transistor was manufactured through a conventional process.

A single crystalline silicon substrate having a crystalline structure of (1 0 0) was prepared. After a gate insulation layer was formed on the substrate, a polysilicon layer was formed on the gate insulation layer. The gate insulation layer and the polysilicon layer were partially etched to form a first gate structure of an NMOS transistor and a second gate structure of a PMOS transistor on the substrate. The first and the second gate structures had lengths of about 0.5 to about 0.6 μm and widths of about 5 μm, respectively.

After spacers were formed on the sidewalls of the first and the second gate structures, N type impurities were implanted into portions of the substrate adjacent to the first gate structure to form first source/drain regions. P type impurities were implanted into portions of the substrate adjacent to the second gate structure to form second source/drain regions. A low temperature oxide layer having a thickness of about 110 Å was formed on the substrate, the first gate structure and the second gate electrode. After a PECVD process was performed to form a silicon nitride layer on the low temperature oxide layer, a thermal treatment was carried out on the substrate to form channel regions having tensile stresses.

Evaluation of Electrical Characteristics of the Exemplary Transistors:

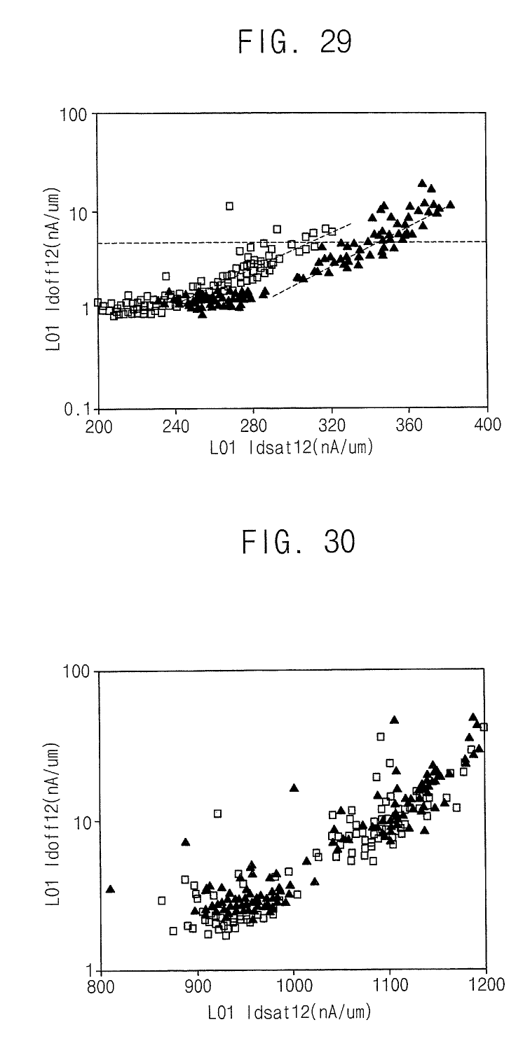

Saturation currents and turn-off currents of a PMOS transistor of Example 1 and a PMOS transistor of Comparative Example were measured. FIG. 29 is a graph illustrating the saturation currents and the turn-off currents that may be obtained for the PMOS transistors according to Example 1 and the Comparative Example. In FIG. 29, an X-axis indicates the saturation currents and a Y-axis denotes the turn-off currents. Additionally, “▴” represents measured currents of the PMOS transistor of Example 1 and “□” denotes measured currents of the PMOS transistor of Comparative Example.

When the turn-off currents of the PMOS transistors are substantially the same, the PMOS transistors having relatively high saturation currents are superior to the PMOS transistors having relatively low saturation currents.

Referring to FIG. 29, when the turn-off currents of the PMOS transistor of Example 1 were the same as those of the PMOS transistor of Comparative Example, the saturation currents of the PMOS transistor of Example 1 may have been substantially higher than those of the PMOS transistor of Comparative Example. Thus, the PMOS transistor of Example 1 may be relatively superior to the PMOS transistor of Comparative Example. The PMOS transistor of Example 1 may have had a higher current gain ratio of about 11% than that of the PMOS transistor of Comparative Example.

Saturation currents and turn-off currents of an NMOS transistor of Example 2 and an NMOS transistor of Comparative Example were measured. FIG. 30 is a graph illustrating the saturation currents and the turn-off currents that may be obtained for the NMOS transistors according to Example 1 and the Comparative Example. In FIG. 30, an X-axis denotes the saturation currents and a Y-axis indicates the turn-off currents. Further, “▴” means measured currents of the NMOS transistor of Example 1 and “□” denotes measured currents of the NMOS transistor of Comparative Example.

Referring to FIG. 30, when the turn-off currents of the NMOS transistor of Example 1 were substantially the same as those of the PMOS transistor of Comparative Example, the saturation currents of the NMOS transistor of Example 1 were substantially the same as those of the NMOS transistor of Comparative Example. Thus, the NMOS transistor of Example 1 and the NMOS transistor of Comparative Example may have substantially similar performances. Although the plasma treatment was carried out on the oxide layer using the nitrogen plasma, the plasma treatment may not affect the electrical characteristics of the NMOS transistor.

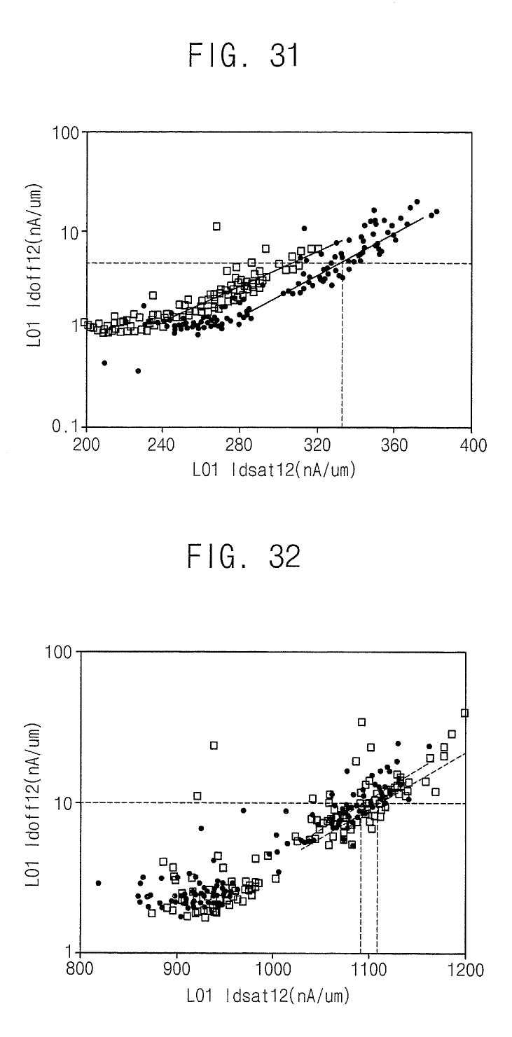

Saturation currents and turn-off currents of a PMOS transistor of Example 2 and a PMOS transistor of Comparative Example were measured. FIG. 31 is a graph illustrating the saturation currents and the turn-off currents that may be obtained for the PMOS transistors according to Example 2 and the Comparative Example. In FIG. 31, an X-axis indicates the saturation currents and a Y-axis denotes the turn-off currents. Additionally, “” indicates measured currents of the PMOS transistor of Example 2 and “□” indicates measured currents of the PMOS transistor of Comparative Example.

Referring to FIG. 31, when the turn-off currents of the PMOS transistor of Example 2 were the same as those of the PMOS transistor of Comparative Example, the saturation currents of the PMOS transistor of Example 2 may be higher than those of the PMOS transistor of Comparative Example. Accordingly, the PMOS transistor of Example 2 may have been relatively superior to the PMOS transistor of Comparative Example. For example, the PMOS transistor of Example 2 has a current higher than that of the PMOS transistor of Comparative Example by about 8%.

Saturation currents and turn-off currents of an NMOS transistor of Example 2 and an NMOS transistor of Comparative Example were measured. FIG. 32 is a graph illustrating the saturation currents and the turn-off currents that may be obtained for the NMOS transistors according to Example 2 and Comparative Example. In FIG. 32, an X-axis indicates the saturation currents and a Y-axis denotes the turn-off currents. Further, “” represents measured currents of the NMOS transistor of Example 2 and “□” means measured currents of the NMOS transistor of Comparative Example.

As illustrated in FIG. 32, when the turn-off currents of the NMOS transistor of Example 2 were substantially the same as those of the PMOS transistor of Comparative Example, the saturation currents of the NMOS transistor of Example 2 may have been substantially the same as those of the NMOS transistor of Comparative Example. Hence, the NMOS transistor of Example 1 and the NMOS transistor of Comparative Example may have substantially similar performances.

According to embodiments of the present invention, upward and lateral diffusions of impurities may be effectively prevented by a diffusion preventing layer, so that a PMOS transistor may have an increased on-current and improved electrical characteristics. Further, channel regions of a CMOS transistor may be more easily formed in a substrate as strained silicon regions such that the CMOS transistor may be operated with a high response speed. When the CMOS transistor is employed in a semiconductor memory device, the semiconductor memory device may have a high performance.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a transistor, the method comprising:
forming a gate electrode stacked on a gate insulation layer pattern on a substrate;
forming impurity regions at portions of the substrate adjacent to the gate electrode by implanting Group III impurities into the portions of the substrate;
forming a diffusion preventing layer on the substrate and covering the gate electrode;
forming a nitride layer on the diffusion preventing layer; and
thermally treating the substrate to form a strained silicon region in the substrate between the impurity regions and to activate the impurities in the impurity regions.

2. The method of claim 1, wherein forming the diffusion preventing layer comprises:
forming an oxide layer on the substrate and covering the gate electrode; and
treating the oxide layer with a plasma generated from at least one of a hydrogen gas, a helium gas, a nitrogen gas, an argon gas, an oxygen gas, and an ozone gas.

3. The method of claim 2, wherein the oxide layer comprises a tensile strained silicon oxide layer or a compressive strained silicon oxide layer.

4. The method of claim 2, wherein treating the oxide layer is performed at one or more temperatures in a range between about 300° C. to about 700° C.

5. The method of claim 1, wherein forming the diffusion preventing layer comprises:
forming an oxide layer on the substrate and covering the gate electrode; and
treating the oxide layer with ultraviolet light.

6. The method of claim 1, further comprising, prior to forming the impurity regions, implanting impurities selected from at least one of germanium, xenon, carbon, and fluorine into the portions of the substrate adjacent to the gate electrode and into a portion of the gate electrode to cause the implanted portions of the substrate and the gate electrode to have non-crystalline structures.

7. A method of manufacturing a transistor, the method comprising:
forming gate structures in a first area and a second area of a substrate, each of the gate structures including a gate electrode stacked on a gate insulation layer pattern;
forming first impurity regions at first portions of the substrate adjacent to the gate structure in the first area by implanting therein first impurities having a first conductivity;
forming second impurity regions at second portions of the substrate adjacent to the gate structure in the second area by implanting therein second impurities having a second conductivity;
forming a diffusion preventing layer on the substrate and covering the gate structures;
forming a nitride layer on the diffusion preventing layer; and
thermally treating the substrate to form a first strained silicon region in the substrate between the first impurity regions and to form a second strained silicon region in the substrate between the second impurity region, and to activate the first and the second impurities in the first and the second impurity regions.

8. The method of claim 7, wherein forming the diffusion preventing layer comprises:
forming an oxide layer on the substrate and covering the gate structures; and
treating the oxide layer with a plasma generated from at least one of a hydrogen gas, a helium gas, a nitrogen gas, an argon gas, an oxygen gas, and an ozone gas.

9. The method of claim 8, wherein the oxide layer comprises a tensile strained silicon oxide layer or a compressive strained silicon oxide layer.

10. The method of claim 8, wherein treating the oxide layer is performed at one or more temperatures in a range between about 300° C. and about 700° C.

11. The method of claim 8, wherein forming the oxide layer comprises at least one of a thermal chemical vapor deposition process using tetraethylorthosilicate, a plasma enhanced chemical vapor deposition process, and a high density plasma-chemical vapor deposition process.

12. The method of claim 8, wherein treating the oxide layer and forming the nitride layer are performed in-situ.

13. The method of claim 8, wherein treating the oxide layer is carried out after forming the nitride layer.

14. The method of claim 7, wherein forming the diffusion preventing layer comprises:
forming an oxide layer on the substrate and covering the gate structures; and
treating the oxide layer with ultraviolet light.

15. The method of claim 14, wherein treating the oxide layer is carried out after forming the nitride layer.

16. The method of claim 14, wherein treating the oxide layer is carried out at one or more temperatures in a range between about 300° C. and about 700° C.

17. The method of claim 7, wherein the diffusion preventing layer has a thickness in a range between about 50 Å and about 300 Å.

18. The method of claim 7, wherein thermally treating the substrate is carried out at one or more temperatures in a range between about 900° C. and about 1,200° C. and in an atmosphere including at least one of nitrogen, argon, and hydrogen.

19. The method of claim 7, wherein the nitride layer is formed at one or more temperatures in a range between about 300° C. and about 500° C. through at least one of plasma enhanced chemical vapor deposition process and a high density plasma-chemical vapor deposition process.

20. The method of claim 7, wherein the nitride layer has a thickness in a range between about 100 Å and about 1,000 Å.

21. The method of claim 7, further comprising forming gate spacers on sidewalls of each of the gate structures.

22. The method of claim 7, further comprising:
removing the nitride layer and the diffusion preventing layer after thermally treating the substrate; and
forming metal silicide patterns on the substrate and each of the gate structures.

23. The method of claim 7, further comprising, prior to forming the first and the second impurity regions, implanting impurities selected from at least one of germanium, xenon, carbon, and fluorine into the first and the second portions of the substrate and into portions of the gate electrodes so that the first and the second portions of the substrate and the implanted portions of the gate electrodes have non-crystalline structures.

24. The method of claim 7, wherein the first impurities comprise phosphorus and/or arsenic, and the second impurities comprise boron and/or boron fluoride.

25. The method of claim 24, further comprising forming a nitride layer pattern in the first area by removing the nitride layer in the second area.

26. A method of manufacturing a metal oxide semiconductor transistor, comprising:
forming gate structures in a first area and a second area of a substrate, each of the gate structures including a gate electrode stacked on a gate insulation layer pattern;
forming first impurity regions at first portions of the substrate adjacent to the gate structure in the first area by implanting therein first impurities having a first conductivity;
forming second impurity regions at second portions of the substrate adjacent to the gate structure in the second area by implanting therein second impurities having a second conductivity;
forming an oxide layer on the substrate and covering the gate electrodes;
treating the oxide layer to form a diffusion preventing layer having increased energy level to further inhibit diffusion of the first and the second impurities;
forming a nitride layer on the diffusion preventing layer; and
thermally treating the substrate to form a first strained silicon region in the substrate between the first impurity regions, to form a second strained silicon region in the substrate between the second impurity regions, and to activate the first and the second impurities in the first and the second impurity regions.

27. The method of claim 26, wherein treating the oxide layer is carried out using a plasma generated from at least one of a hydrogen gas, a helium gas, a nitrogen gas, an argon gas, an oxygen gas, and an ozone gas.

28. The method of claim 26, wherein treating the oxide layer comprises irradiating the oxide layer with ultraviolet light.

29. The method of claim 26, wherein the first impurities comprise phosphor and/or arsenic, and the second impurities comprise boron and/or boron fluoride.

30. The method of claim 26, further comprising forming a nitride layer pattern in the first area by partially removing the nitride layer in the second area.
